(19) United States
(12) Patent Application Publication
(10) Pub. No.: US 2002/0037651 A1
(43) Pub. Date: Mar. 28, 2002

(54) METHOD FOR MINIMIZING DAMAGE OF PROCESS CHARGING PHENOMENA

(76) Inventor: TZUNG-HAN LEE, TAIPEI CITY (TW)

Correspondence Address: THOMAS T. MOGA, POWELL, GOLDSTEIN, FRAZER & MURPHY, LLP, 1001 PENNSYLVANIA AVE, N.W., SUITE 600, WASHINGTON, DC, 20004, US

(21) Appl. No.: 09/438,829

(22) Filed: Nov. 12, 1999

(51) Int. Cl. H01L 21/302; H01L 21/461

(52) U.S. Cl. 438/710

(57) ABSTRACT

A method for minimizing damage of process charging phenomena during fabrication of integrated circuits is proposed by the invention. The presented method comprises following essential steps: First, provides a substrate and defines a plurality of cell regions and a plurality of scribe lines on the substrate, where any cell region is separated from other cell regions by these scribe lines. Second, forms a plurality of basic structures inside cell regions, where these basic structures are formed in and on the substrate. Third, forms an interpoly dielectric layer on the substrate, where the interpoly dielectric layer is located inside both cell regions and scribe lines. Fourth, forms a plurality of via holes inside scribe lines where bottom of any via hole is below surface of the substrate and top of any said via hole is on surface of the interpoly dielectric layer. Fifth, forms a conductive layer on the interpoly dielectric layer, where the conductive layer also fills these via holes. Sixth, patterns the conductive layer such that conductive layer inside cell regions and conductive layer inside scribe lines are separated. Seventh, treats conductive layer such that a plurality of structures are formed inside cell region. Eighth, forms a dielectric layer on conductive layer. Significantly, owing to the fact that conductive layer is formed inside both cell regions and scribe lines, and conductive layer inside scribe layers are electrically coupled to substrate, during seventh steps conductive layer inside scribe layers will behaves as lightning arraster and then damage of process charging is efficiently reduced. Furthermore, when multilevel metallization process is used to fabricate dies, the proposed method also is effective by repeating the third step to the seventh step of the method.

### BACKGROUND OF THE INVENTION

1. Field of the Invention

This invention is in the field of fabrication of integrated circuit, and more particularly directed to a method that minimizes damage of process charge phenomena by surrounding cell regions by conductive structures.

2. Description of the Prior Art

When critical dimension of integrated circuits are less then about 0.25 μm or diameter of wafer is larger than about six inches, selectivity and uniformity are dominating factors of etching process. Therefore, conventional reactive ions etch (RIE) is gradually replaced by high density plasma (HDP) etch that not only can provide plasma in low pressure but also can reduce damage of ions bombardment and provide good uniformity by controlling density of plasma and energy of ions separately. No matter how, because etching process of high density plasma usually is accompanied with formation of excess ions that is harmful for integrated circuits, it is unavoidable that structures of integrated circuits are damaged. As usual, owing to these excess ions are produced during fabrication process of integrated circuits, it is called as process charging phenomena.

According principle of semiconductor devices, it is obvious that quality of gate oxide is a key factor of semiconductor devices. Whenever charges appear in and on gate, characteristics of gate are varied for electrical environment is varied. Varied characteristics of gates comprise threshold voltage, breakdown voltage. In addition, plasma etching process usually induces formation of oxide trapped charge that randomly distributes in and on wafer.

Moreover, during fabrication of integrated circuits, metal or polysilicon structures are typically used to form interconnect or part of gate. Thus for metal oxide semiconductor (MOS) device, long metal or polysilicon interconnect lines (antenna) that may accumulate charge during plasma etching may be connected to the gate of MOS device. Because of the relatively high capacitance of the MOS gate, charge build up occurs disproportionately at the gate of MOS device. Because the gate usually is a thin oxide, it is particularly sensitive to damage due to plasma etch charge build up.

The performance of MOS device is degraded by charge build-up caused by certainly plasma etching process, especially the HDP etching process. Plasma charging can produce various forms of damage in the material being etched, comprising (1) formation of electron traps in gate oxides and (2) displaced and implanted atoms at the material surface due to ion bombardment. The trapped charge decreases breakdown voltage of the oxide and if not annealed out, and can cause shift in the threshold voltages resulting in reliability failures. Further, the surface states formed at the oxide-semiconductor interface degrade transistor characteristics such as subthreshold slope, transconductance, and device lifetime under hot electron stress.

Till now, some methods are proposed to minimize charging damage. For example, one method is that increasing the alloy cycle time to anneal out surface states. Another conventional method is that addition of a thin dielectric layer on top of any metal layer (polysilicon layer). It is believed to reduce the efficiency with which the antenna (the large sections of metal or polysilicon interconnect lines connected to the gate) collects charge from the plasma. No matter how, though these methods have been shown to reduce the damage of process charging, these methods are complexity to the fabrication process, increase process cost, and impact the cycle time.

Therefore, there is a need for a method that not only efficiently minimize damage of process charging but also does not require special processing steps which increase complexity of fabrication process and also increases both process cycle time and total cost.

### SUMMARY OF THE INVENTION

It is an object of the invention to reduce damage of process charging phenomena during fabrication of integrated circuits.

It is another object of the invention to provide a method that efficiently minimizes process charging phenomena but without modifying structure of integrated circuits.

It is a further object of the invention to provide a manufacturable method that efficiently minimizes damages of process charging phenomena without significantly modifying fabrication of integrated circuits.

In order to explain the invention, an embodiment is used to present a specific method that efficiently minimizes damages of process charging phenomena by surrounding dies with conductive structures that behave as lightning arraster.

The presented method comprises following essential steps: First, provides a substrate and defines a plurality of cell regions and a plurality of scribe lines on the substrate, where any cell region is separated from other cell regions by these scribe lines. Second, forms a plurality of basic structures inside cell regions, where these basic structures are formed in and on the substrate. Third, forms an interpoly dielectric layer on the substrate, where the interpoly dielectric layer is located inside both cell regions and scribe lines. Fourth, forms a plurality of via holes inside scribe lines where bottom of any via hole is below surface of the substrate and top of any said via hole is on surface of the interpoly dielectric layer. Fifth, forms a conductive layer on the interpoly dielectric layer, where the conductive layer also fills these via holes. Sixth, patterns the conductive layer such that conductive layer inside cell regions and conductive layer inside scribe lines are separated. Seventh, treats conductive layer such that a plurality of structures are formed inside cell region. Eighth, forms a dielectric layer on conductive layer.

Significantly, because conductive layer is formed inside both cell regions and scribe lines, and conductive layer inside scribe layers are electrically coupled to substrate, they will behave as lightning arraster and then charge during metallization process are conducted to ground. Therefore, damage of process charging is efficiently reduced. Furthermore, when multilevel metallization process is used to fabricate dies, the proposed method also is effective by repeating the third step to the seventh step of the method.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a top view of a wafer that schematically represents mechanism of the proposed invention;

FIG. 2A to FIG. 2D are a series of cross-section views of a wafer that schematically represents fabrication of a preferred embodiment of the proposed invention; and

FIG. 3 is a cross-section view of a wafer that schematically represents fabrication of an alternative embodiment of the present invention.

### DESCRIPTION OF THE PREFERRED EMBODIMENT

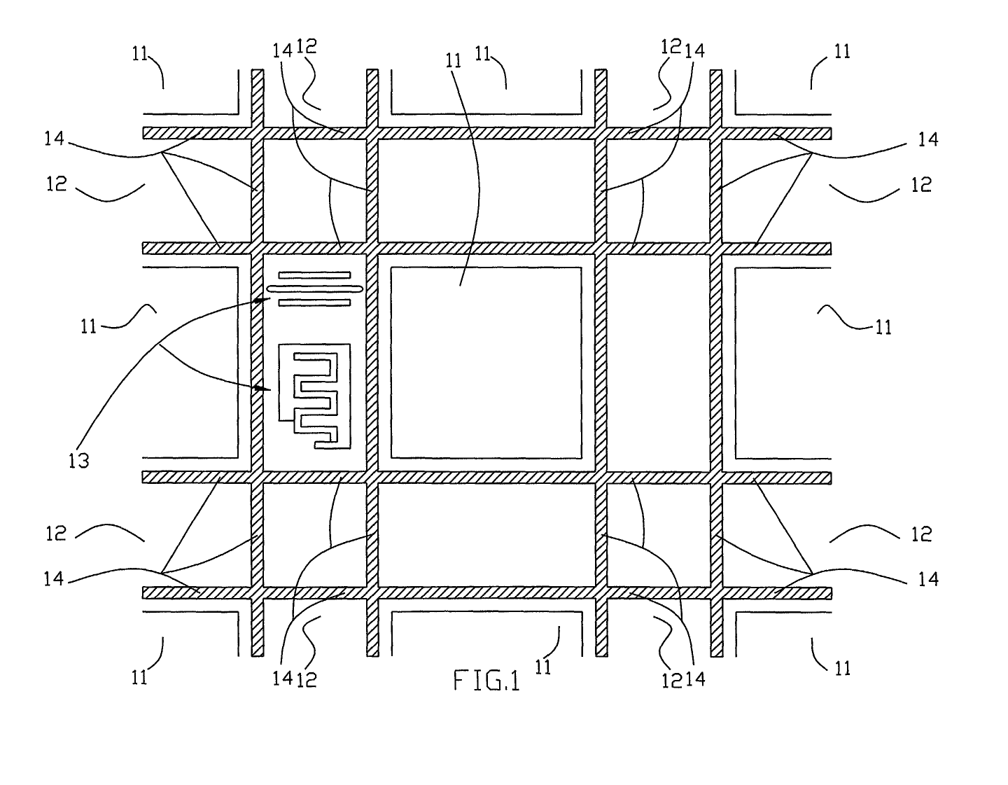

Referring to FIG. 1 where a top view of a wafer is provided to schematically represents mechanism of the proposed invention. There are many cell regions 11 and many scribe line 12, and any cell region 11 is separated from other cell regions 11 by scribe lines 12. Beside, these also are some auxiliary conductive structures 13 inside scribe lines such as test key, alignment key and CD bar. Herein, auxiliary conductive structures do not contact with any dies inside cell region 11, and also is electrically isolated from any die.

Mechanism of the proposed invention is surrounding any cell region 11 by conductive structures 14 that are electrically coupled with ground of wafer and behave as lightning arraster. Obviously, during fabrication process such as plasma etching process, owing to conductive structures 14 are electrically coupled with ground of wafer and unfinished structures of any die is completely enclosed by conductive structures 14, excess charge are attracted by conductive structures 14 and are conducted to the ground. Therefore, quantity of charge that stay inside cell region 11 is decreased and then damage of charge is efficiently minimized. In other words, damage of process charging phenomena is efficiently minimized even the process charging phenomena still happens. Additional, conductive structures 14 can not contact with auxiliary conductive structures 13, and also is electrically isolated from auxiliary conductive structures 13. That is to say that function of auxiliary conductive structures 13 is not affected by conductive structures 14.

Moreover, FIG. 1 is only a sketch map. And shape of conductive structures 14 is not limited by it. In fact, in order to increase the efficiency of attracting charge the surface of conductive structures 14 should be as large as possible. Beside, in order to decrease the barrier of charge motion, distance between conductive structures 14 and any cell region 11 should be as smaller as possible. No matter how, it is important that conductive structures 14 and any cell region 11 must be separated to avoid function of integrated circuits are degraded by unexpected connection.

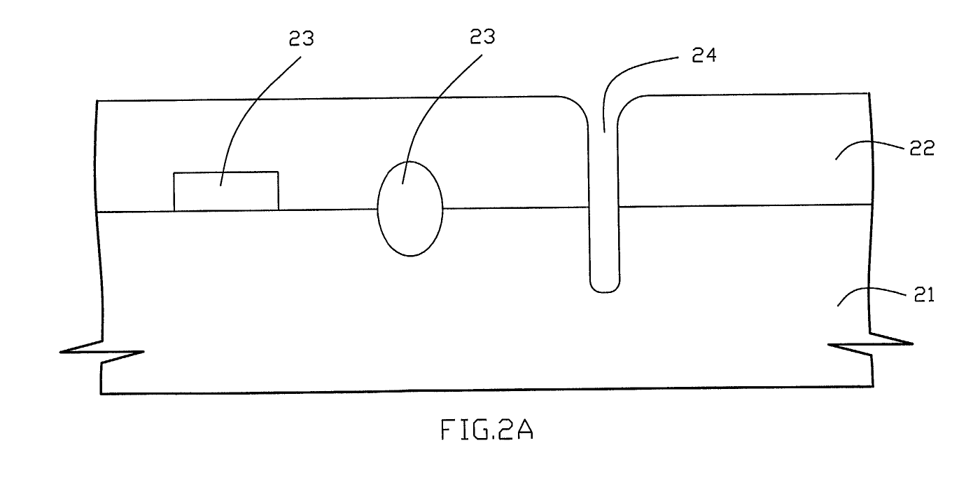

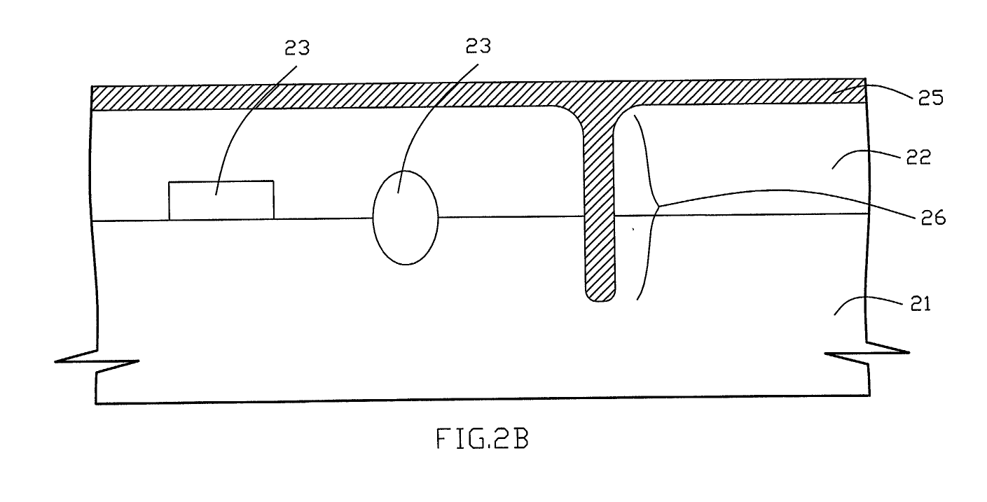

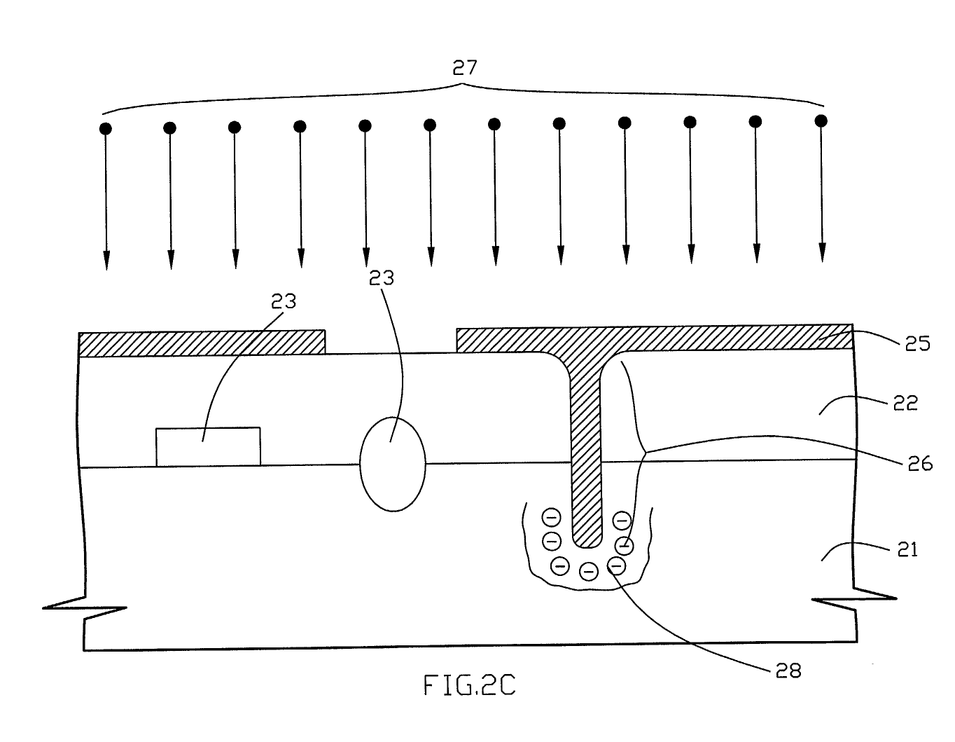

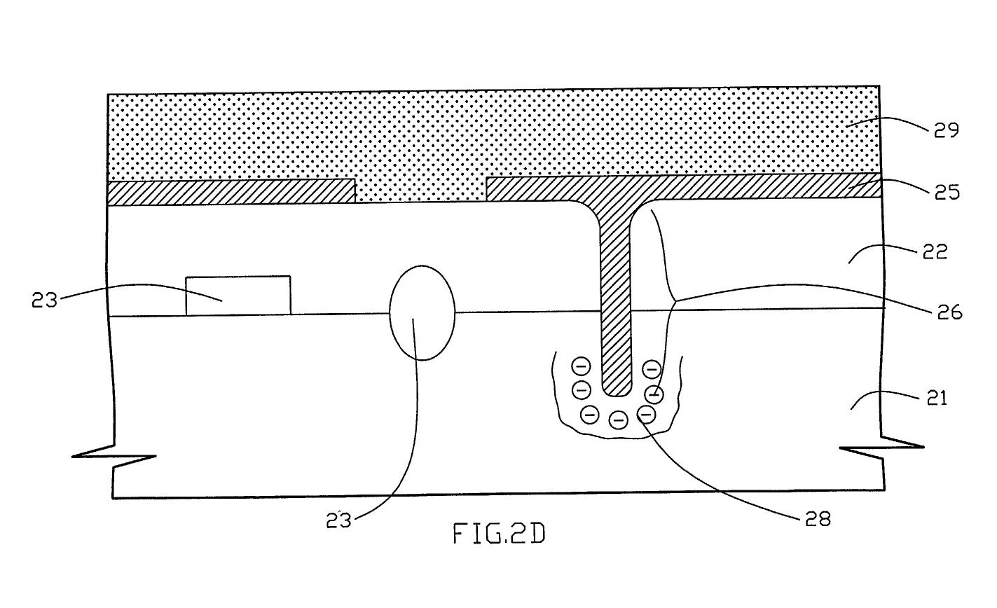

To further explain the present invention, FIG. 2A to FIG. 2D are employed. Where many cell regions and scribe lines have been defined on a wafer. Of course, the invention further comprises a plurality of auxiliary conductive structures that locate on substrate 21 and inside scribe lines. Herein, available varieties of said auxiliary conductive structures comprise test key, alignment key and CD bar. No matter how, in order to simplify the figure, only a cell region and a scribe line are illustrated and only one step of the present method is detailed illustrate. Furthermore, key steps of the invention comprise following steps:

First of all steps, as shown in FIG. 2A, form interpoly dielectric layer 22 on substrate 21, where a plurality of basic structures 23 are formed inside the cell region and located in and on said substrate. Herein, interpoly dielectric layer 22 comprises silicon dioxide that is formed by a chemical vapor deposition method. Further, substrate 21 comprises silicon substrate and basic structures 23 comprise gate and isolation. Then form via holes 24 inside scribe lines, where bottom of via hole 24 is below surface of substrate 21 and top of via hole 24 is on surface of interpoly dielectric layer 22.

And then as FIG. 2B shows, form conductive layer 25, such as metal layer or polysilicon layer, on interpoly dielectric layer 22, where conductive layer 25 also fills via holes 24 and then plug 26 is formed. Because bottom of via hole 24 is below surface of substrate 21, plug 26 is electrically coupled said substrate 21. In addition, conductive layer 25 does not contact with alleged auxiliary conductive structures. Next, pattern conductive layer 25 such that conductive layer 25 is divided into two parts. First part is inside the cell regions and second part is inside scribe lines. Moreover, two parts are separated and do not contact with each other. Beside, because second part of conductive layer 25 connects with plug 26, it is natural that second part of conductive layer 25 and plug 26 conjugate to form a conductive structure that locates inside scribe line and is electrically coupled with substrate 21.

Consequentially, referring to FIG. 2C, treat conductive layer 25 such that a plurality of structures are formed inside the cell region. Herein, methods for treating conductive layer 25 comprise dry etching, plasma etching and high density plasma etching process. Obviously, except applied method is wet etching, otherwise conductive layer 25 is bombarded by a plurality of particles 27.

As well known, particles 27 usually are charged particles. Then when particles 27 collide with conductive layer 25 or interpoly dielectric layer 22, charge 28 usually is released or trapped by conductive layer 25 or interpoly dielectric layer 22. Therefore, because plug 26 is electrically coupled with substrate 21, charge 28 will be attracted by plug 26 and is conducted to ground of substrate 21. Thus, though charge still is released during fabrication process, but residuary quantity of charge 28 that inside cell region is efficiently minimized. The advantage is more important when high density plasma etching process is employed for process charge phenomena of HDP etching process is stronger than other plasma etching process.

Finally, as FIG. 2D shows, form dielectric layer 29 on conductive layer 25, where available varieties of dielectric layer 29 comprise phosphosilicate glass.

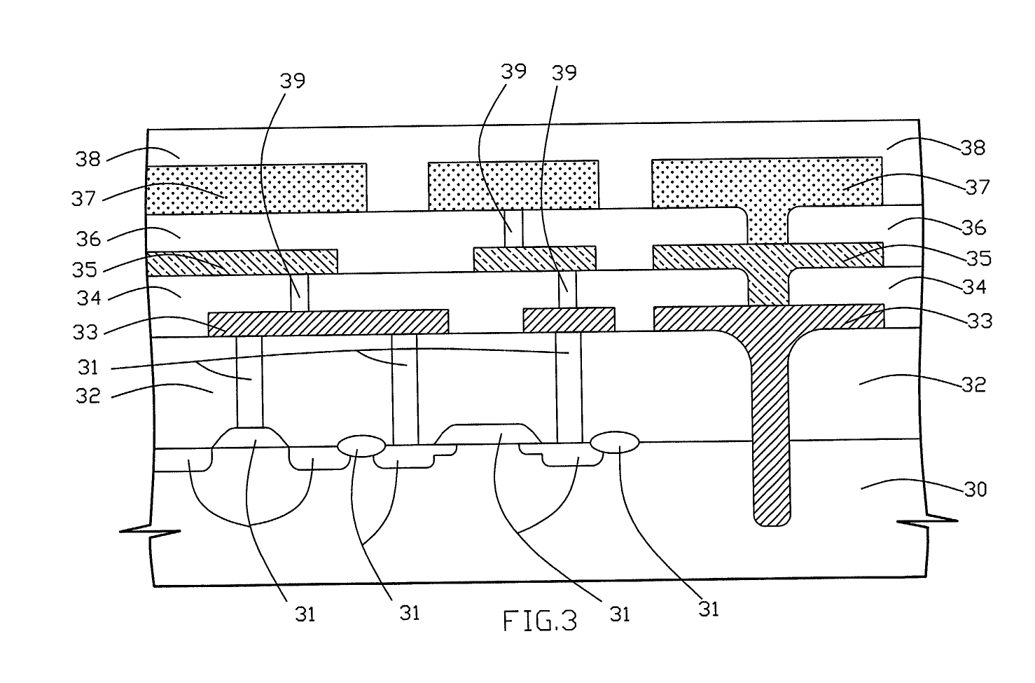

Of course, though only one conductive layer is employed in previous embodiment, the present invention is not limited by it. Obviously, the invention also is suitable when multilevel metallization process is used as is discussed in below paragraphs and FIG. 3.

Referring to FIG. 3 where application of multilevel metallization process is included. First of all, substrate 30 is provided and then a plurality of cell regions and a plurality of scribe lines are defined on substrate 30. Herein, any cell region is isolated from other cell regions by scribe lines. Then, a plurality of basic structures 31 are formed inside cell region regions and are located in and on said substrate.

Therefore, as discussed in previous embodiment, first dielectric layer 32 is formed on substrate 30 and via hole is formed inside scribe line where bottom of via hole is below surface of substrate 30. Then first metal layer 33 is formed on first dielectric layer 32 and us used to fill the via hole to form a plug. And then after first metal layer 33 is treated to form required metallization structure, second dielectric layer 34 is formed on first dielectric layer 32 and covers first metal layer 33. Certainly, because multilevel metallization process is used, another via hole is formed inside scribe line and bottom of this via hole is contacted with first metal layer 33. And then second metal layer 35 is formed on second dielectric layer 34 and fills the via hole such that second metal layer 35 is electrically coupled with substrate 30. Then after second metal layer 35 is treated to form required metallization structure, third dielectric layer 36 is formed on second dielectric layer 34 and covers second metal layer 35. Same process can be repeated again to form third metal layer 37, required metallization structure and fourth dielectric layer 38 such that a triple metallization structure is formed. In addition, it should be noted that fabricating process of connects 39 is not introduced in above discussion.

Obviously, the embodiment can be expanded to multilevel metallization process without any difference. And then whenever a dry etching process, especially a plasma etching process, is used to treat a metal layer such a metallization structure is formed inside cell region, conductive structure inside scribe line can behave as an equivalent lightning arraster such that damage of process charging phenomena is effectively minimized.

Moreover, advantage of the embodiment is that equivalent lighting arraster is formed with required metallization structure simultaneous. In other words, it does not require any specific fabrication process to form the equivalent lighting arraster. Accordingly, fabrication process of the present invention will not be too complicated to be manufacturable, and there is no issues such as increase process cost and impact the cycle time.

While the invention has been described by previous embodiment, the invention is not limited there to. To the contrary, it is intended to cover various modifications and the scope of these claims therefore should be accorded to the broadest interpretation so as to encompass all such modifications and similar arrangement, procedures and products.

What is claimed is:

1. A method for minimizing damage of process charging phenomena, said method comprising:
providing a substrate;
defining a plurality of cell regions and a plurality of scribe lines on said substrate, wherein any said cell region is separated from other said cell regions by said scribe lines;
forming a plurality of basic structures inside said cell regions, wherein said basic structures are located in and on said substrate;
forming an interpoly dielectric layer on said substrate, wherein said interpoly dielectric layer is located inside both said cell regions and said scribe lines;
forming a plurality of via holes inside said scribe lines, wherein bottom of each said via hole is below surface of said substrate and top of each said via hole is on surface of said interpoly dielectric layer;
forming a conductive layer on said interpoly dielectric layer, wherein said conductive layer also fills said via holes such that a plurality of plugs are formed, said plugs are electrically coupled with said substrate;
patterning said conductive layer such that said conductive layer inside said cell regions and said conductive layer inside said scribe lines are separated;
treating said conductive layer such that a plurality of structures are formed inside said cell region; and
forming a dielectric layer on said conductive layer.

2. The method according to claim 1, wherein said substrate comprises silicon substrate.

3. The method according to claim 1, further comprising a plurality of auxiliary conductive structures that locate on said substrate and inside said scribe lines.

4. The method according to claim 3, wherein said auxiliary conductive structures are not contacted with said conductive layer.

5. The method according to claim 3, wherein available varieties of said auxiliary conductive structures comprise test key, alignment key and CD bar.

6. The method according to claim 1, wherein said basic structures comprise gate and isolation.

7. The method according to claim 1, wherein said interpoly dielectric layer comprises silicon dioxide.

8. The method according to claim 7, wherein said silicon dioxide is formed by a chemical vapor deposition method.

9. The method according to claim 1, wherein said conductive layer comprises polysilicon layer.

10. The method according to claim 1, wherein said conductive layer comprises metal layer.

11. The method according to claim 1, wherein methods for treating said conductive layer comprise dry etching.

12. The method according to claim 1, wherein methods for treating said conductive layer comprise plasma etching.

13. The method according to claim 1, wherein methods for treating said conductive layer comprise high density plasma etching process.

14. The method according to claim 1, wherein said dielectric layer comprises phosphosilicate glass.

15. A method for reducing process charging during fabrication of integrated circuit, said method comprising:
providing a substrate;
defining a plurality of cell regions and a plurality of scribe lines on said substrate, wherein any said cell region is isolated from other said cell regions by said scribe lines;
forming a plurality of basic structures inside said cell region regions, wherein said basic structures are formed in and on said substrate; and
forming a plurality of dielectric layers on said substrate where consecutive dielectric layers are separated by a conductive layers, wherein each said conductive layer is bifurcated into a first part inside said cell region regions and a second part inside said scribe lines, wherein a plurality of via holes are formed inside said scribe lines and filled by said conductive layers, and bottom of each said via hole is below surface of said substrate.

16. The method according to claim 15, further comprising patterning said first part of each said conductive layer such that a plurality of structures are formed over said cell region regions.

17. The method according to claim 16, wherein methods for forming said structures comprise high density plasma etching process.

18. The method according to claim 15, further comprising a plurality of auxiliary conductive structures that locate on said substrate and inside said scribe line.

19. The method according to claim 18, wherein said auxiliary conductive structures are not contacted with said conductive layer.

20. The method according to claim 18, wherein available varieties of said auxiliary conductive structures comprise test key, alignment key and CD bar.
